(19) United States
(12) Patent Application Publication
(10) Pub. No.: US 2009/0246715 A1
(43) Pub. Date: Oct. 1, 2009

(54) PLATING METHOD AND METHOD OF FORMING MAGNETIC POLE

(75) Inventors: Yasunori Kouchi, Kawasaki (JP); Masaya Kato, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/246,252

(22) Filed: Oct. 6, 2008

(30) Foreign Application Priority Data
Mar. 27, 2008 (JP) 2008-082546

(51) Int. Cl. G03F 7/20

(52) U.S. Cl. 430/324

(57) ABSTRACT

The plating method is capable of firmly adhering a resist pattern on a plating base in case that, for example, a main magnetic pole of a vertical recording magnetic head is formed by using the resist pattern and accurately configurating a sectional shape of a plated pattern. The plating method comprises the steps of: applying an alkoxylsilyl propyl amino triazine dithiol solution, which is formed by dissolving alkoxylsilyl propyl amino triazine dithiol acting as molecular glue in a solvent, onto the plating base; volatilizing the solvent to form a molecular glue layer; applying resist onto the plating base coated with the molecular glue layer; optically exposing and developing the resist to expose a part of the plating base; and plating the exposed part of the plating base coated with the molecular glue layer.

### BACKGROUND OF THE INVENTION

The present invention relates to a plating method and a method of forming a magnetic pole, more precisely relates to a plating method for forming structural parts of a thin film magnetic head, cable patterns of a circuit board, etc. and a method of forming a magnetic pole.

These days, storage densities of magnetic storage units and recording media are highly increased, so improving performance of thin film magnetic heads has been required. Thus, write-gaps of the magnetic heads and end faces of magnetic poles for writing signals must be narrowed, and the magnetic heads must be highly accurately produced.

For example, a vertical recording magnetic head has a main magnetic pole, which faces a recording medium for recording signals thereon, and a return yoke. An end face of the main magnetic pole seen from the air bearing surface side is formed into an inverted trapezoid, whose width on the read-element side is narrower than that on the return yoke side. The main magnetic pole is formed by a plating method disclosed in Japanese Laid-Open Patent publication No. 2006-322054 or a method in which a magnetic film is formed and etched, by a dry process, to form the main magnetic pole.

In the dry process, the etching process is performed by focused ion beam etching (FIB) or ion milling. However, in case of the FIB, mass productivity must be low; in case of the ion milling, it is difficult to highly precisely configurate the magnetic pole.

On the other hand, in case of employing the plating method, the configuration and the size of the main magnetic pole are defined by a resist pattern, so the configuration of the magnetic pole can be highly precisely controlled by highly precisely forming the resist pattern.

In case of forming the main magnetic pole by plating, the production method comprises the steps of: forming a film of a plating base on an insulating layer, which has been formed on a reproducing head, by, for example, electroless plating; forming a resist layer on the plating base; optically exposing and developing the resist layer so as to form a prescribed resist pattern; and forming the main magnetic pole by electrolytic plating, in which the plating base is used as a seed layer.

In the method, the resist cannot be sufficiently adhered onto the plating base formed by electroless plating, so a part of the resist will be peeled from the plating base and an electroless-plated film will be formed in a space between the plating base and the peeled resist. Therefore, the main magnetic pole cannot be accurately formed into the inverted trapezoid.

### SUMMARY OF THE INVENTION

The present invention was conceived to solve the above described problems.

An object of the present invention is to provide a suitable plating method, which is capable of firmly adhering a resist pattern on a plating base in case that, for example, a main magnetic pole of a vertical recording magnetic head is formed by using the resist pattern and accurately configurating a cross sectional shape of a plated pattern.

Another object is to provide a method of forming a magnetic pole by applying said plating method.

To achieve the objects, the present invention has following constitutions.

Namely, the plating method, in which a resist pattern is formed on a plating base and a prescribed plated layer is formed, comprises the steps of: applying an alkoxylsilyl propyl amino triazine dithiol (TESTD) solution, which is formed by dissolving alkoxylsilyl propyl amino triazine dithiol acting as molecular glue in a solvent, onto the plating base; volatilizing the solvent so as to form a molecular glue layer; applying resist onto the plating base coated with the molecular glue layer; optically exposing and developing the resist so as to expose a part of the plating base, whose configuration corresponds to a pattern of the plated layer; and plating the exposed part of the plating base coated with the molecular glue layer.

The method may further comprise the step of rinsing the molecular glue layer with isopropyl alcohol.

In the method, the solvent may be volatilized at a temperature of 150-180° C. in the volatilizing step.

In the method, sulfur molecules of alkoxylsilyl propyl amino triazine dithiol in the molecular glue layer may bond to the resist.

Next, the method of forming a magnetic pole, in which a resist pattern is formed on a plating base and the magnetic pole is formed by plating, comprises the steps of: applying an alkoxylsilyl propyl amino triazine dithiol solution, which is formed by dissolving alkoxylsilyl propyl amino triazine dithiol acting as molecular glue in a solvent, onto the plating base; volatilizing the solvent so as to form a molecular glue layer; applying resist onto the plating base coated with the molecular glue layer; optically exposing and developing the resist so as to expose a part of the plating base, whose configuration corresponds to a pattern of the magnetic pole; and plating the exposed part of the plating base coated with the molecular glue layer.

The method may be applied to form a main magnetic pole of a vertical magnetic head.

By employing the plating method of the present invention, in case of, for example, forming a main magnetic pole of a vertical recording magnetic head by using a resist pattern, the resist pattern can be firmly adhered on the plating base, so that a plated pattern having an accurate cross sectional shape can be formed.

### BRIEF DESCRIPTION OF THE DRAWINGS

Embodiments of the present invention will now be described by way of examples and with reference to the accompanying drawings, in which:

FIG. 1 is a sectional view of a thin film magnetic head produced by the method of the present invention;

FIGS. 2A-2F are explanation views showing production steps of a main magnetic pole of the thin film magnetic head;

FIG. 3 is an explanation view of a plating base on which a TESTD solution is applied;

FIG. 4 is an explanation view of the plating base on which a molecular glue layer is formed;

FIG. 5 is an explanation view of the plating base in which a resist pattern is formed on the molecular glue layer;

FIG. 6A shows plan views and sectional views of main magnetic poles formed by a conventional plating method;

FIG. 6B shows plan views and sectional views of main magnetic poles formed by the plating method of the present invention; and

FIGS. 7A-7D are explanation views showing an example of a production process to which the plating method of the present invention is applied.

### DETAILED DESCRIPTION OF THE EMBODIMENTS

Preferred embodiments of the present invention will now be described in detail with reference to the accompanying drawings. In the following description, a method of forming structural elements of a thin film magnetic head will be explained as a first embodiment.

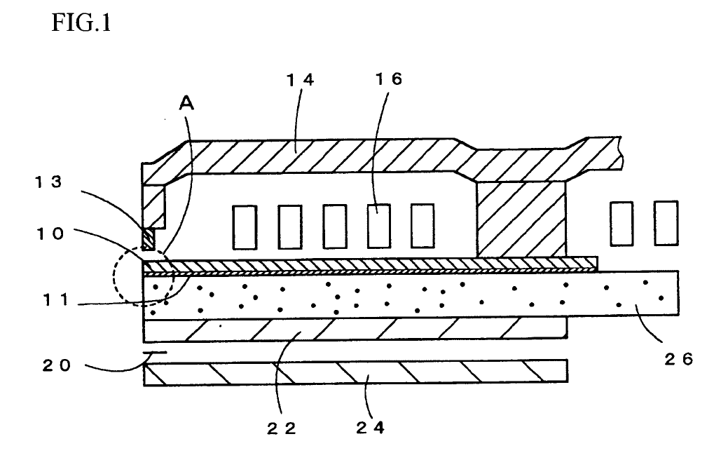

FIG. 1 is a sectional view of a thin film magnetic head for vertical magnetic recording.

The thin film magnetic head has: a main magnetic pole 10 acting as a write-head; a trailing shield 13; a return yoke 14; a coil 16 for writing signals; and a read-head including a MR element 20, an upper shield 22 and a lower shield 24. An insulating layer 26 composed of alumina is formed between the upper shield 22 and the main magnetic pole 10, and insulating layers composed of, for example, alumina are formed between the main magnetic pole 10 and the coil 16, between the coil 16 and the return yoke 14, and between the MR element 20, the upper shield 22 and the lower shield 24.

The thin film magnetic head is produced by forming films of the shield layers 22 and 24, the MR element 29, the main magnetic pole 10, the coil 16 and the return yoke 14 on a substrate composed of Al₂O₃—TiC in order and patterning them to have prescribed configurations.

As described above, in the thin film magnetic head for vertical magnetic recording, the end face of the main magnetic pole facing a recording medium is formed into the inverted trapezoid, whose width on the read-element 20 side is narrower than that on the return yoke 14 side.

The feature of the thin film magnetic head of the present embodiment is a molecular glue layer 15 (see FIG. 4) being formed on a plating base 11, which acts as a base layer of the main magnetic pole 10.

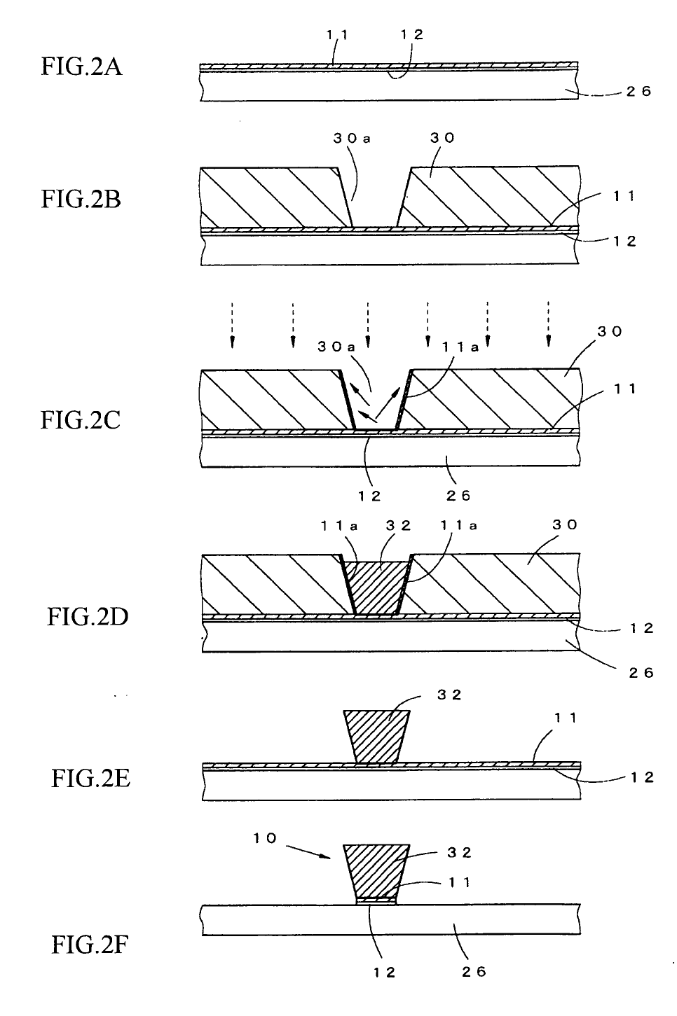

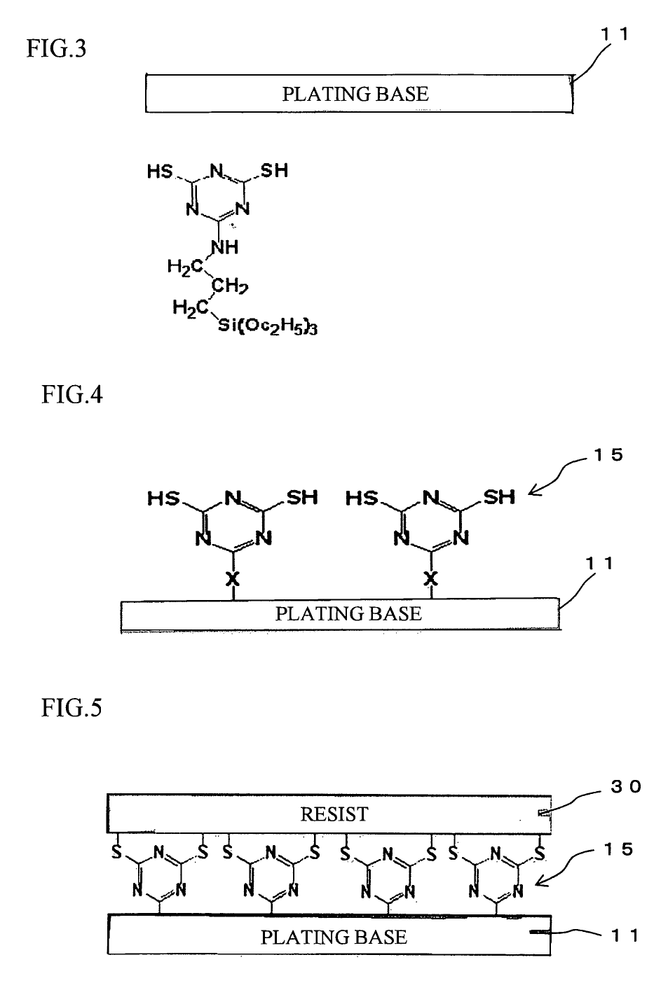

FIGS. 2A-2F are explanation views showing production steps of the main magnetic pole 10 of the thin film magnetic head. FIGS. 2A-2F are the views of a part “A” shown in FIG. 1 seen from the end face side.

In FIG. 2A, an adhesion layer 12 is formed on the insulating layer 26, and then the plating base 11 is formed thereon. The adhesion layer 12 tightly adheres the plating base 11 onto the surface of the insulating layer 26. The adhesion layer 26 is formed by evaporating or sputtering Ti, Ta, Cr, Nb, etc.

In the present embodiment, the plating base 11 is composed of Ru (ruthenium). The plating base 11 is formed by evaporating or sputtering Ru. The plating base 11 will be used as a plating seed layer, so it has a suitable thickness, e.g., 500 angstrom, for obtaining a prescribed resistance value. Note that, the material of the plating base 11 is not limited to Ru.

In the present embodiment, as described above, the molecular glue layer 15 (see FIG. 4) is formed on the plating base 11.

The molecular glue layer 15 is formed by the steps of: applying an alkoxylsilyl propyl amino triazine dithiol (TESTD) solution, which is formed by dissolving alkoxylsilyl propyl amino triazine dithiol acting as molecular glue in a solvent, onto the plating base; and volatilizing the solvent so as to form the molecular glue layer.

The TESTD solution may be applied onto the plating base 11 by soaking a member including the plating base 11 into the TESTD solution or spin-coating the surface of the plating base with the TESTD solution.

Preferably, the solvent is volatilized at a temperature of about 150-180° C., and a time length of the volatilization may be about 5-10 minutes.

Since the TETD can be dissolved in alcohol solvents, so alcohol solvents may be used as the solvent for dissolving the TESTD. Preferably, concentration of the TESTD is about 0.1-100 g/l.

Preferably, the surface of the molecular glue layer 15 is rinsed with alcohol after volatilizing the solvent and drying the molecular glue layer 15. Various residues exist on the surface of the dried molecular glue layer 15, so the surface is rinsed with alcohol to remove the residues. Preferably, isopropyl alcohol is capable of evenly rinsing the molecular glue layer 15, so that the molecular glue layer 15 can have even thickness.

The TESTD has the following molecular formula, and alkoxylsilyl group of the TESTD is capable of firmly bonding to the plating base 11 (see FIG. 4).

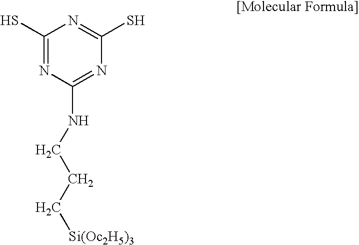

Note that, the molecular glue layer 15 is very thin film like a unimolecular film, so it is not shown in FIGS. 2A-2F.

In FIG. 2B, a resist pattern 30 is formed on the surface of the plating base 11 coated with the molecular glue layer. Resist coating the surface of the plating base 11 is optically exposed and developed to form the resist into a prescribed pattern. Namely, a concave part 30a is formed in the resist pattern 30 so as to form a front end part of the main magnetic pole 10, whose cross sectional shape is the inverted trapezoid. The plating base 11 composed of Ru is exposed as the inner bottom face of the concave part 30a. Note that, as described above, the surface of the plating base 11 is coated with the molecular glue layer.

As shown in FIG. 5, sulfur molecules of the TESTD in the molecular glue layer 15 firmly bond to the resist of the resist pattern 30.

Therefore, the resist pattern 30 is firmly adhered to the plating base 11 by the molecular glue layer 15, so that peeling the resist patter 30 from the plating base 11 can be prevented.

After forming the resist pattern 30, the resist is hydrophilically treated. In FIG. 2C, the resist is treated by irradiating O₂ plasma as the hydrophilic treatment.

By irradiating O₂ plasma toward the resist, the surface of the resist pattern 30 is changed from a hydrophobic surface to a hydrophilic surface. Further, Ru of the plating base 11 is oxidized to RuO₄, and the volatilized RuO₄ sticks onto inner faces of the concave part 30a as residues 11a.

In the present embodiment, the plating base 11 is composed of Ru, and an oxide of Ru (RuO₄) is a volatile compound. Therefore, RuO₄ generated by the hydrophilic treatment sticks onto the inner faces of the concave part 30a as the residues 11a.

As described above, by the hydrophilic treatment, the residues 11a stick onto the inner faces of the concave part 30a. By the residues 11a sticking on the inner faces of the concave part 30a, the resist pattern 30 including the concave part 30a is not deformed even if the hydrophilic treatment is performed for the resist pattern 30. Generally, the resist is volatilized and a concave part or a groove is widened by performing the hydrophilic treatment of the resist pattern 30. However, by volatilizing the volatile compounds 11a from the plating base 11, widening the concave part or the groove is restrained.

After performing the hydrophilic treatment of the resist pattern 30 as described above, a magnetic film (high saturation magnetic flux density film) 32 is formed in the concave part 30a by electrolytic plating, in which the plating base 11 is used as an electric power feeding layer. FIG. 2D shows the state in which the magnetic film 32 has been formed by the electrolytic plating.

Note that, after performing the hydrophilic treatment, the surface of the volatile metal layer 11a is activated by dilute acid, etc. as a pretreatment of the plating. The magnetic film 32 can be formed in the concave part 30a by not only the electrolytic plating but also electroless plating. In case of performing the electrolytic plating, a direct current or a pulse current can be used.

The magnetic film 32 may be composed of, for example, FeCo, FeCoα (α=Pd, Pt, Rh, Mo, Zr), CoNiFe, NiFe or NiFeα (α=Pd, basis of structural parts of the thin film magnetic head.

As described above, the resist pattern 30 is firmly adhered to the plating base 11 by the molecular glue layer 15, so that the resist pattern 30 is not peeled from the plating base 11. Therefore, the problem of the conventional technology, i.e., invading a plated film into a space between the resist pattern and the plating base while forming the main magnetic pole 32 in the concave part 30a of the resist pattern 30, can be solved, and the main magnetic pole 32 can be accurately formed into the desired inverted trapezoid.

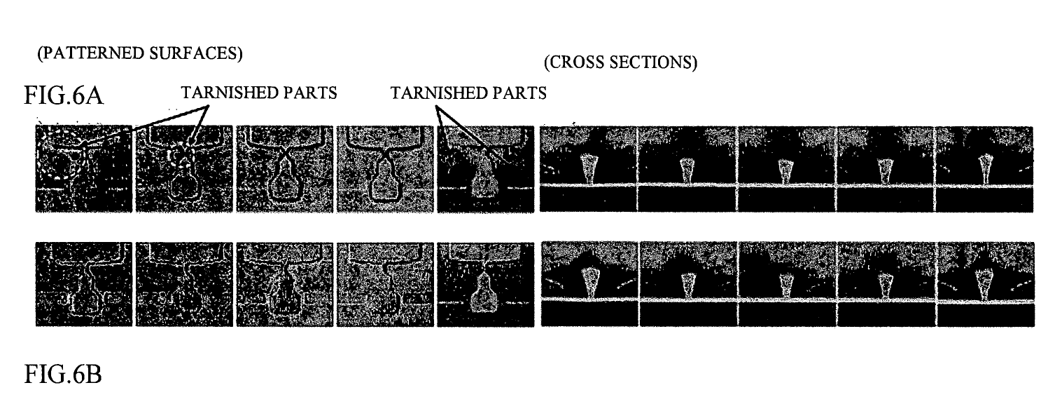

FIG. 6A shows plan views and sectional views of main magnetic poles formed by the conventional plating method wherein no molecular glue layer is formed between the plating base and the resist pattern; FIG. 6B shows plan views and sectional views of main magnetic poles formed by the plating method of the present embodiment wherein the molecular glue layer is formed between the plating base and the resist pattern.

In the plan views of FIG. 6A, plated films invade into peeled parts around the main magnetic poles, and the peeled parts are tarnished. In the sectional view of the rightmost main magnetic pole, a base part of the main magnetic pole is narrowed by the invasion of the plated film. Therefore, the main magnetic poles having the desired cross sectional shapes cannot be formed by the conventional method.

On the other hand, in the plan views of FIG. 6B, no tarnished parts exist in the main magnetic poles produced by the method of the present embodiment. Further, as shown in the sectional views, the main magnetic poles having the desired cross sectional shapes can be formed.

In FIG. 2E, the resist pattern 30 is removed after forming the magnetic film 32. The resist pattern 30 can be chemically dissolved and removed. When the resist pattern 30 is removed, the residues, i.e., RuO₄, sticking on the inner faces of the concave part 30a are also removed together with the resist pattern 30. Note that, even if the residues are partially left on side faces of the magnetic film 32, the residues are nonmagnetic matters, so they never influence characteristics of the thin film magnetic head.

After removing the resist pattern 30, disused parts of the plating base 11 and the adhesion layer 12, which are exposed on the surface of the insulating layer 26, are removed. In FIG. 2F, the disused parts of the plating base 11 and the adhesion layer 12 are removed, and the main magnetic pole 10 is formed on the insulating layer 26. When the disused parts of the plating base 11 and the adhesion layer 12 are removed by ion milling, specific parts of the plating base 11 and the adhesion layer 12 are covered with the magnetic film 3. Further, the plating base 11 and the adhesion layer 12 are extremely thin films, so the exposed parts of the plating base 11 and the adhesion layer 12 can be easily selectively removed. The specific part of the plating base 11 left under the main magnetic pole 10 never badly influences the characteristics of the thin film magnetic head.

As described above, in the present embodiment, the resist pattern 30 is adhered on the plating base 11 by the molecular glue layer 15 composed of the TESTD, so that the resist pattern 30 can be firmly adhered on the plating base 11 and no spaces formed therebetween. Therefore, the main magnetic pole 10, whose cross sectional shape is the desired inverted trapezoid, can be formed.

In the above described embodiment, the present invention is applied to a method of forming the plated pattern of the main magnetic pole 10 of the vertical recording magnetic head, but the plating method of the present invention may be applied to not only the method of forming the main magnetic pole 10 but also methods of forming other structural elements of thin film magnetic heads.

For example, the plating method can be applied to a method of forming the trailing shield 13, which is placed to face the main magnetic pole 10 as shown in FIG. 1.

Further, the plating method of the present invention may be applied to a method of forming a magnetic pole of a horizontal recording magnetic head.

The plating method of the present invention is not limited to the above described production process of the thin film magnetic head.

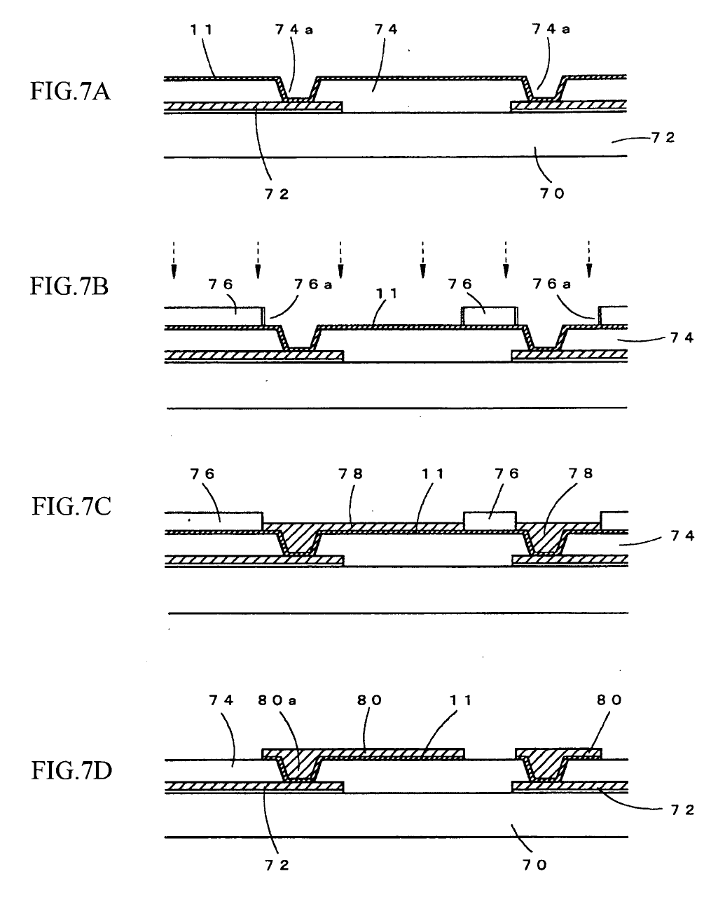

FIGS. 7A-7D are explanation views, in which the plating method of the present invention is applied to a production process of a multilayered circuit board as a second embodiment.

In FIG. 7A, an insulating layer 74, which is composed of, for example, polyimide film, is formed on a base layer 70, on which cable patterns 72 have been formed. Via holes 74a are formed in the insulating layer 74 by, for example, laser means, and then an electroless-plated film 11, which acts as the plating base, is formed.

In FIG. 7B, after forming the electroless-plated film 11, the molecular glue layer (not shown) composed of the TESTD is formed on the electroless-plated film 11, as well as the first embodiment. Resist is adhered on the electroless-plated film 11 by the molecular glue layer, and then the resist is optically exposed and developed so as to form resist patterns 76. The resist patterns 76 are patterned to expose specific parts of the insulating layer 74, on which cable patterns 80 will be formed.

Then, electrically conductive layers 78 are formed in concave parts, i.e., pattern grooves 76a, of the resist patterns 76 by plating, in which the electroless-plated film 11 is used as an electric power feed layer.

In FIG. 7C, the conductive layers 78 have been completely formed in the pattern grooves 76a by the plating. The conductive layers 78 are copper films having prescribed thicknesses, and they are formed by electrolytic copper plating.

Next, the resist patterns 76 are removed, and disused parts of the electroless-plated film 11, which are not coated with the conductive layers 78, are also removed, so that prescribed cable patterns 80 are formed on the surface of the insulating layer 74 (see FIG. 7D).

In FIG. 7D, the cable patterns 80 in the upper layer and the cable patterns 72 in the lower layer are electrically connected by vias 80a. By the above described process, the multilayered circuit board can be produced.

In the method of producing the circuit board too, the resist patterns 76 can be firmly adhered onto the plating base 11 by the molecular glue layer composed of the TESTD, so that the cable patterns 80 can be accurately formed.

The invention may be embodied in other specific forms without departing from the spirit of essential characteristics thereof. The present embodiments are therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A method of forming a magnetic pole, in which a resist pattern is formed on a plating base and the magnetic pole is formed by plating,
comprising the steps of:
applying an alkoxylsilyl propyl amino triazine dithiol solution, which is formed by dissolving alkoxylsilyl propyl amino triazine dithiol acting as molecular glue in a solvent, onto the plating base;
volatilizing the solvent so as to form a molecular glue layer;
applying resist onto the plating base coated with the molecular glue layer;
optically exposing and developing the resist so as to expose a part of the plating base, whose configuration corresponds to a pattern of the magnetic pole; and
plating the exposed part of the plating base coated with the molecular glue layer.

2. The method according to claim 1,
wherein the magnetic pole is a main magnetic pole of a vertical magnetic head.

3. The method according to claim 1,
further comprising the step of rinsing the molecular glue layer with isopropyl alcohol.

4. The method according to claim 2,
further comprising the step of rinsing the molecular glue layer with isopropyl alcohol.

5. The method according to claim 1,
wherein the solvent is volatilized at a temperature of 150-180° C. in the volatilizing step.

6. The method according to claim 2,
wherein the solvent is volatilized at a temperature of 150-180° C. in the volatilizing step.

7. The method according to claim 3,
wherein the solvent is volatilized at a temperature of 150-180° C. in the volatilizing step.

8. The method according to claim 4,
wherein the solvent is volatilized at a temperature of 150-180° C. in the volatilizing step.

9. The method according to claim 1,
wherein sulfur molecules of alkoxylsilyl propyl amino triazine dithiol in the molecular glue layer bond to the resist.

10. The method according to claim 2,
wherein sulfur molecules of alkoxylsilyl propyl amino triazine dithiol in the molecular glue layer bond to the resist.

11. The method according to claim 3,
wherein sulfur molecules of alkoxylsilyl propyl amino triazine dithiol in the molecular glue layer bond to the resist.

12. The method according to claim 4,
wherein sulfur molecules of alkoxylsilyl propyl amino triazine dithiol in the molecular glue layer bond to the resist.

13. The method according to claim 5,
wherein sulfur molecules of alkoxylsilyl propyl amino triazine dithiol in the molecular glue layer bond to the resist.

14. The method according to claim 6,
wherein sulfur molecules of alkoxylsilyl propyl amino triazine dithiol in the molecular glue layer bond to the resist.

15. The method according to claim 7,
wherein sulfur molecules of alkoxylsilyl propyl amino triazine dithiol in the molecular glue layer bond to the resist.

16. The method according to claim 8,
wherein sulfur molecules of alkoxylsilyl propyl amino triazine dithiol in the molecular glue layer bond to the resist.

17. A plating method, in which a resist pattern is formed on a plating base and a prescribed plated layer is formed,
comprising the steps of:
applying an alkoxylsilyl propyl amino triazine dithiol solution, which is formed by dissolving alkoxylsilyl propyl amino triazine dithiol acting as molecular glue in a solvent, onto the plating base;
volatilizing the solvent so as to form a molecular glue layer;
applying resist onto the plating base coated with the molecular glue layer;
optically exposing and developing the resist so as to expose a part of the plating base, whose configuration corresponds to a pattern of the plated layer; and
plating the exposed part of the plating base coated with the molecular glue layer.

18. The method according to claim 17,
further comprising the step of rinsing the molecular glue layer with isopropyl alcohol.

19. The method according to claim 17,
wherein the solvent is volatilized at a temperature of 150-180° C. in the volatilizing step.

20. The method according to claim 18,
wherein the solvent is volatilized at a temperature of 150-180° C. in the volatilizing step.
